(19) United States
(12) Patent Application Publication
(10) Pub. No.: US 2025/0280506 A1
(43) Pub. Date: Sep. 4, 2025

(54) HEAT EXCHANGERS ON CIRCUIT BOARDS

(71) Applicant: Intel Corporation, Santa Clara, CA (US)

(72) Inventors: Jeff Ku, Taipei (TW); Smit Kapila, Bangalore (IN); Min Suet Lim, Gelugor (MY); Lance Lin, Taipei (TW); Arnab Sen, Bengaluru (IN); Shuo Man Yuan, Taipei (TW)

(21) Appl. No.: 18/593,345

(22) Filed: Mar. 1, 2024

(51) Int. Cl. H05K 7/20; G06F 1/20; H05K 1/02

(52) U.S. Cl. CPC H05K 7/20154; G06F 1/203; H05K 1/0204; H05K 1/0209; H05K 7/20336

(57) ABSTRACT

Heat exchangers on edges of circuit boards are disclosed. An apparatus includes: a housing including an outlet for air flow; a circuit board; and a heat exchanger extending along an edge of the circuit board. The heat exchanger includes a first side and a second side opposite the first side. The first side faces away from the outlet, and the second side faces toward the outlet. The edge of the circuit board is closer to the second side of the heat exchanger than the edge is to the first side of the heat exchanger.

### FIELD OF THE DISCLOSURE

This disclosure relates generally to electronic cooling systems and, more particularly, to heat exchangers on circuit boards.

### BACKGROUND

Many electrical components such as integrated circuit packages produce heat when in operation. Accordingly, many electronic devices containing such components implement fans to force air across the heat producing electrical components to draw away heat and cool the system. In some cases, an array of fins (e.g., as part of a heat sink or other heat exchanger (e.g., a stacked heat exchanger)) is thermally coupled to the heat producing component and positioned in the flow path of the forced air. As a result, the heat exchanger draws heat from the electrical component and the fins provide increased surface area to transfer the heat to the air to facilitate the cooling of the system

### BRIEF DESCRIPTION OF THE DRAWINGS

FIG. 1 is a front view of an example computing device constructed in accordance with teachings disclosed herein.

FIG. 2 is a back view of the example computing device of FIG. 1.

FIG. 3 is a schematic diagram of a cross-sectional view of the example computing device of FIGS. 1 and 2.

FIG. 4 is an isometric view of another example computing device constructed in accordance with teachings disclosed herein.

FIG. 5 is an isometric view of the example computing device of FIG. 4 with the external chassis or housing removed to expose internal components of the example computing device.

FIG. 6 is an enlarged view of a portion of the example heat exchanger of the example computing device of FIG. 5.

FIG. 7 is an enlarged cross-sectional view of a portion of the example heat exchanger of the example computing device of FIG. 6.

FIG. 8 is another example computing device constructed in accordance with teachings disclosed herein.

FIG. 9 illustrates an example tab at the end of the example clip supporting the example heat exchanger of FIG. 8.

FIG. 10 is another example computing device constructed in accordance with teachings disclosed herein.

FIG. 11 is another example computing device constructed in accordance with teachings disclosed herein.

FIG. 12 is another example computing device constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Many computing devices include one or more fans to help cool the processor and/or other integrated circuits in the device. Providing adequate heat transfer to cool a system is particularly challenging in portable computing devices such as tablets and laptops because of the limited space for fans and other cooling system components. One approach to cooling heat producing electrical components (e.g., integrated circuit packages) in such computing devices is through the implementation of a hyperbaric cooling system. In hyperbaric cooling systems, one or more fans draw cool air from an external environment through an inlet in the chassis or housing of the computing device, thereby creating significant air pressure within the housing. The high pressure causes the hot air to be blown through one or more outlets. As the air is being forced through the housing, the air draws heat from the heat producing components thereby cooling the system.

A significant factor contributing to the effectiveness or efficiency of a hyperbaric cooling system is the open-air ratio of the outlet for the hot air. As used herein, an open-air ratio is a measure of the free or open space within the cross-sectional area of an outlet compared to the overall cross-sectional area of the outlet. The open-air ratio is often expressed as a percentage. If the outlet is defined by an opening with no obstructions, the open-air ratio will be 100%. However, in many instances, the outlet is covered by (and/or includes) a grill or mesh to block larger particles or objects (e.g., a user's fingers) from passing through the opening. In such instances, the open-air ratio will be less than 100% because the overall area of the outlet is partially obstructed by the grill or mesh. Thus, a higher open-air ratio corresponds to a greater portion of the overall cross-sectional area of the outlet being open or unobstructed, which leads to better heat transfer because of the larger area through which the hot air can pass through the outlet and dissipate heat from the heat producing components within the computing device.

In known laptops that implement hyperbaric cooling systems, the hot air outlet is often an elongate opening that extends along an edge of the base of the chassis or housing of the laptop. Often, the chassis includes ribs that extend across the elongate opening to provide structural support and/or to block external objects (e.g., a user's fingers) from being inserted into the computing device (e.g., to protect the user and to protect the internal components). These ribs provide an obstruction across the outlet, thereby reducing the open-air ratio of the outlet. The impact of such ribs on the open-air ratio depends on the size and spacing of the ribs. In some instances, the ribs are spaced apart with an intervening gap of no more than 1.0 millimeter (mm) to meet safety requirements with the thickness of the ribs typically ranging from 1.0 mm to 2.0 mm depending on the material used for the ribs. Such outlet designs have an open-air ratio of approximately 45%. In some instances, the ribs can be spaced farther apart with a separate mesh positioned behind and/or between the ribs. Frequently, the individual strands or wires of the mesh are much finer (e.g., thinner) than the ribs so as to obstruct less of the cross-sectional area of the outlet. For instance, some metal meshes have an open-air ratio of approximately 62%. When such meshes are combined with the ribs across an outlet provided for structural support, the overall open-air ratio can be between 50% and 55%.

Some known laptops use an array of heat exchanger fins instead of a mesh or grill. That is, the fins are arranged with a spacing of no more than 1.0 mm apart to meet safety requirements without the need for a separate wire mesh. Further, in some instances, the heat exchanger fins may be thermally coupled to the heat producing electrical components to draw heat from such components and further facilitate heat transfer to the forced air as it passes between the fins and through the outlet. Some known laptop designs that use heat exchanger fins achieve an open-air ratio up to 71%. While this approach provides an improved open-air ratio relative to a wire mesh implementation, it comes at the cost of space within the housing because of the width of the fins relative to the negligible thickness of a mesh. In particular, some known devices implement heat exchanger fins having a width of approximately 6 mm. As a result, there is a loss in space available for a circuit board to support components and/or to route signals between such components. For example, assuming the heat exchanger fins (and associated outlet) extend 154 mm along an edge of the circuit board, there is a total loss of 924 square millimeters (6 mm×154 mm).

Examples disclosed herein implement an outlet design that achieves an open-air ratio of more than 71% (e.g., at least 72%, at least 73%, at least 74%, at least 75%, at least 76%, at least 77%, etc.). This is achieved using an array of heat exchanger fins as discussed above. However, unlike existing techniques that sacrifice board space for the fins, examples disclosed herein do not affect the size of a circuit board. This is possible because the fins do not extend continuously the full distance across the outlet and, instead, attach to one or both sides of the circuit board along the edge of the board. In some examples, the fins on either side of the circuit board are thermally coupled by a thermally conductive connection that wraps around the edge of the circuit board. While the presence of the fins on one or both sides of the circuit board prevent other components from being mounted to the circuit board at that location, the internal space within the circuit board remains available to provide electrical routing between components mounted at other locations on the circuit board. This additional space for electrical routing within a circuit board can reduce the complexity and, thus, the cost of manufacturing the circuit board. In some examples, at least some of the internal space within the circuit board includes a thermally conductive slug or heat pipe that facilitates the thermal coupling of heat producing components on the circuit board with the heat exchanger fins to improve heat transfer to the forced air passing through the fins. Additionally or alternatively, in some examples, the fins are thermally coupled to the heat producing components by way of a vapor chamber external to the circuit board.

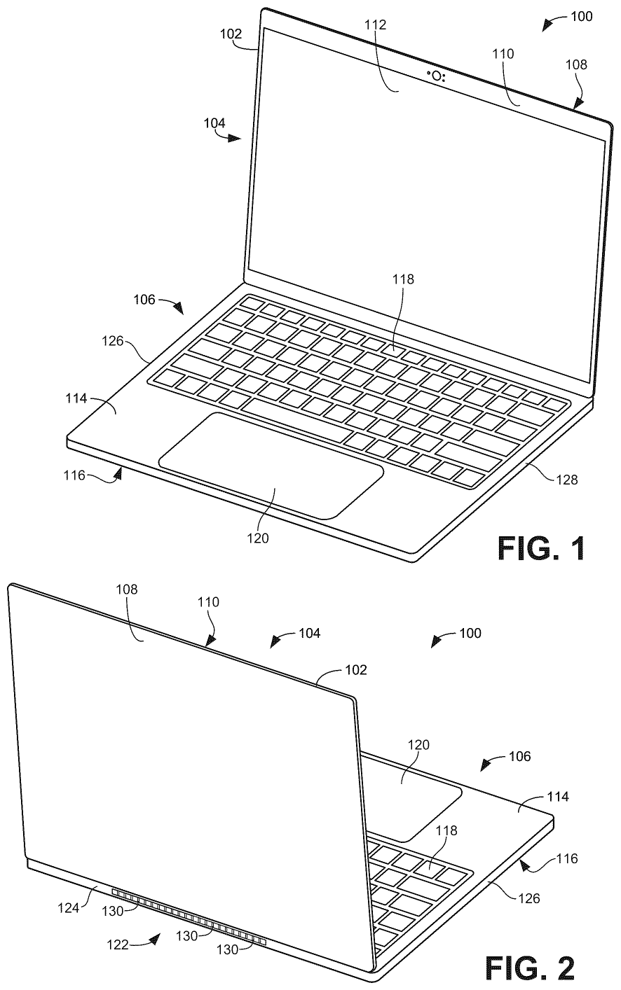

FIG. 1 illustrates a front view of an example computing device 100 constructed in accordance with teachings disclosed herein. FIG. 2 illustrates a back view of the example computing device 100 of FIG. 1. In the illustrated example, the computing device 100 is a laptop computer that implements one or more fans to facilitate the cooling of heat producing components (e.g., electronic components) during operation. In other examples, the computing device 100 can be any other type of electronic device that cools heat producing components (e.g., electronic components) using forced air blown by one or more fans.

The example computing device 100 of FIG. 1 includes a chassis or housing 102 that includes a lid 104 and a base 106. In some examples, the lid 104 includes an A cover 108 and a B cover 110. A display screen 112 is disposed in the B cover 110 of the lid 104. In some examples, the display screen 112 is a touch sensitive display (e.g., a touchscreen). In some examples, the base 106 includes a C cover 114 and a D cover 116. In this example, a keyboard 118 and a touchpad 120 are disposed in the C cover 114. In some examples, the lid 104 is rotatably coupled to the base 106 via a hinge to enable the lid 104 to be moved (e.g., opened and closed) relative to the base 106.

In the illustrated example the base 106 of the housing 102 contains heat producing components such as, for example, one or more integrated circuit packages and/or other electronic components. In some examples, the integrated circuit packages include and/or correspond to chips, microchips, a semiconductor substrate coupling multiple circuit elements, a system on chip (SoC), programmable circuitry including one or more programmable microprocessors such as Central Processor Units (CPUs), Field Programmable Gate Arrays (FPGAs), Graphics Processor Units (GPUs), Digital Signal Processors (DSPs), XPUs, Network Processing Units (NPUs), one or more microcontrollers, Application Specific Integrated Circuits (ASICs), etc. In this example, excess heat produced by such electronic components is dissipated by the flow of forced air blown by one or more fans in the base 106 as detailed further below. Accordingly, in some examples, the base 106 includes one or more air openings that serve as inlets to intake cool (e.g., ambient) air from the environment surrounding the computing device 100. Further, in some examples, the base 106 includes one or more openings that serve as outlets to expel hot air that has been heated due to the transfer of heat from the heat producing components to the air.

More particularly, in this example, the base 106 includes an opening or outlet 122 positioned at a center (e.g., a center outlet) of a rear edge 124 of the base 106. As shown in the illustrated example, the outlet 122 is elongate along the rear edge 124 with a length that is considerably greater than its height. In some examples, the outlet 122 can be different sizes and/or at different locations from what is shown in the illustrated example. For instance, in some examples, the outlet 122 may be shorter or longer than what is shown in FIG. 2. In some examples, there may be more than one outlet spaced apart along the rear edge 124 of the base 106. Additionally or alternatively, in some examples, the outlet 122 (and/or one or more other outlet(s)) may be positioned on one or both side edges 126, 128 of the base 106. Further, in some examples, the outlet 122 (and/or one or more other outlet(s)) may be on the underside of the computing device 100 (in the D cover 116). In other examples, the outlet 122 can be at any other suitable location on the computing device 100. In the illustrated example of FIGS. 1 and 2, the inlet(s) for ambient air are not visible because they are on the underside of the computing device 100. In other examples, the inlet(s) can additionally or alternatively be on the side edges 126, 128, the rear edge 124, and/or at any other suitable location.

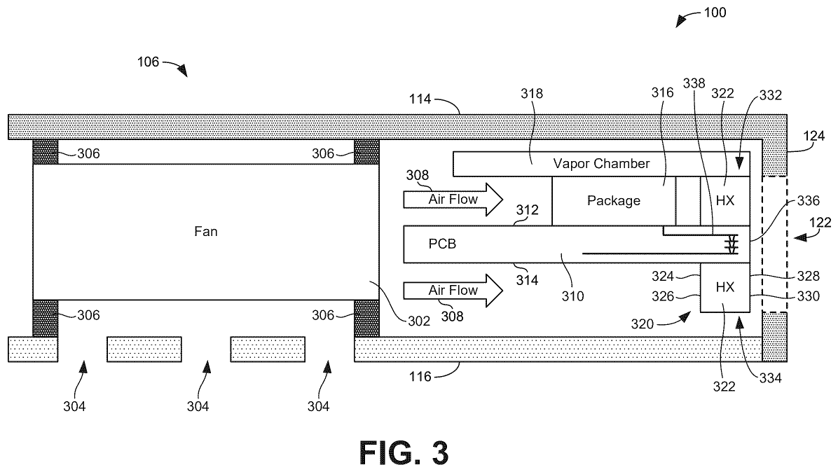

In some examples, the outlet 122 includes one or more ribs 130 distributed along the length of the outlets to provide structural support to the outlet 122. In some examples, the ribs 130 are an integral portion of the housing 102. That is, in some examples, the ribs 130 are part of the C cover 114 and/or the D cover 116. In some examples, the ribs 130 are spaced relatively close together to prevent objects from entering into the housing 102 through the outlet 122 (e.g., objects larger than the spacing of the ribs 130). In some examples, the spacing of the ribs 130 is not important to block objects from entering the housing 102 because a separate mesh or grill extends across the gaps between the ribs 130. More particularly, in examples, disclosed herein, such a mesh or grill is implemented by an array of heat exchanger fins (e.g., the heat exchanger fins 322 shown in FIG. 3) positioned within the base 106 adjacent the outlet 122 as discussed in further detail below.

The outlet 122 has an open-air ratio defined by the proportion or percentage of the overall area of the outlet 122 that is unobstructed by any object. The overall area of the outlet 122 corresponds to the height of the outlet 122 multiplied by the width or length of the outlet. Obstructions within the outlet affecting the open-air ratio include the ribs 134 and the heat exchanger fins 322 positioned along the length of the outlet 122. The thickness and spacing of the ribs 134 as well as the thickness and spacing of the fins 322 determine the open-air ratio for the outlet 122 as discussed further below.

FIG. 3 is a schematic diagram of a cross-sectional view of the example computing device 100 of FIGS. 1 and 2. More particularly, FIG. 3 illustrates a cross-sectional view of a portion of the base 106 showing the rear edge 124 of the base 106 by the outlet 122. For purposes of clarity, the ribs 130 shown in FIG. 2 are omitted in FIG. 3. FIG. 3 shows internal components between the C cover 114 and the D cover 116. In this example, the rear edge 124 of the base 106 is defined by the C cover 114 that extends downward toward the edge to the D cover 116, which is limited to the bottom or underside of the base 106. Thus, as shown in FIG. 3, the outlet 122 is in the C cover 114. In other examples, the rear edge 124 is defined by the D cover 116 that extends upwards toward the C cover 114. In such examples, the outlet 122 is in the D cover 116. In other examples, both the C cover 114 and the D cover 116 may define portions of the rear edge 124 and, thus, portions of the outlet 122.

As shown in the illustrated example of FIG. 3, the computing device 100 includes a fan 302 positioned adjacent one or more openings or inlets 304 on the underside of the base 106 (e.g., in the D cover 116). As mentioned above, in some examples, the inlets 304 can be positioned at any other suitable location on the base 106. In this example, the fan 302 is relatively flat or thin (to fit within the relatively thin space between the C and D covers 114, 116) and held in place by one or more gaskets 306. The fan 302 draws air from an external environment through the inlets 304 and into the housing of the base 106, thereby increasing the pressure inside the base 106 (e.g., a hyperbaric condition) to produce a flow of forced air (air flow 308) towards the outlet 122. As shown in the illustrated example, the air flow 308 extends across a circuit board 310 (e.g., a printed circuit board (PCB)). More particularly, in this example, the air flow 319 travels across a first (top) surface 312 of the circuit board 310 as well as a second (bottom) surface 314 of the circuit board 310. In other examples, the air flow 308 may travel predominately (e.g., exclusively) across one of the surfaces 312, 314 of the circuit board 310.

As shown in FIG. 3, as the air flow 308 travels towards the outlet 122, the air flow 308 passes over one or more heat producing components 316 (e.g., an integrated circuit package) to cool the components by drawing away heat produced therefrom. Further, in this example, the air flow 308 passes across a vapor chamber 318 thermally coupled to the heat producing component 316. The vapor chamber 318 draws heat away from the heat producing component 316 and then transfers at least some of the heat to the air flow 308 to be dissipated to the external environment after the air is expelled through the outlet 122. In some examples, as represented in FIG. 3, the vapor chamber 318 is also thermally coupled to a heat exchanger 320 to pass heat from the heat producing component 316 to the heat exchanger 320.

In some examples, the vapor chamber 318 includes a metal exterior that is electrically coupled to the fins 322 (also made of metal). In some such examples, the vapor chamber 318 and/or the fins 322 are grounded on the circuit board to define a closed metal shield that can mitigate radio frequency interference (RFI) and/or electromagnetic interference (EMI). Further, in some such examples, a metal mesh with gaps less than approximately 2 mm (e.g., less than 1 mm) is electrically coupled to the heat exchanger fins 322 and/or the vapor chamber 318 to improve the RFI/EMI mitigation.

In the illustrated example of FIG. 3, the heat exchanger 320 includes an array of heat exchanger fins 322 aligned with the direction of the air flow 308 at a position adjacent to and upstream of the outlet 122 so that the air flow sequentially passes through the heat exchanger 320 and then out through the outlet 122. Thus, in this example, the heat exchanger 320 includes a first (upstream) side 324 corresponding to leading (upstream) edges 326 of the fins 322 and a second (downstream) side 328 corresponding to trailing (downstream) edges 330 of the fins 322. That is, the fins 322 extend in in a direction aligned with the direction of the air flow 308 and transverse to the first and second sides 324, 328 of the heat exchanger 320. As shown in FIG.

3, the first side 324 of the heat exchanger 320 (and the leading edges 326 of the associated fins 322) face toward the heat producing component 316 and away from the outlet 122. By contrast, the second side 328 of the heat exchanger 320 (and the trailing edges 330 of the associated fins 322) face away from the heating producing component 316 and toward the outlet 122. Due to this arrangement, before the air flow 308 reaches the opening, the air flow 308 passes through the fins 322. As a result, the forced air will draw heat away from the fins 322 to further facilitate the dissipation of heat generated by the heat producing component 316.

In the illustrated example of FIG. 3, the heat exchanger 320 includes a first portion 332 on the first surface 312 of the circuit board 310 and a second portion 334 on the second surface 314 of the circuit board 310. That is, unlike known cooling systems that position a heat exchanger beyond the outer edge of a circuit board, in the illustrated example of FIG. 3, the circuit board 310 extends between the two portions 332, 334 of the heat exchanger 320 with an outer edge 336 of the circuit board 310 closer to the second side 328 of the heat exchanger 320 than the outer edge 336 is to the first side 324 of the heat exchanger 320. An advantage of arranging the heat exchanger 320 on the surfaces 312, 314 of the circuit board 310 is that it enables an increase in the size of the circuit board 310. While this extra board space does not provide space for components to be mounted to the board 310 (because that is where the heat exchanger 320 is located), it at least provides extra space for electrical routing within the board 310, thereby reducing the cost and/or complexity of the design of the circuit board 310. That is, as shown in the illustrated example of FIG. 3, the circuit board 310 includes electrical routing 338 (e.g., electrical circuit path(s), trace(s), via(s), reference plane(s), etc.) at locations laterally between the first and second sides 324, 328 of the heat exchanger 320 (e.g., between the first and second portions 332, 334 of the heat exchanger 320). In other words, the electrical routing 338 extends closer to the outlet 122 (and closer to the outer edge 336 of the circuit board 310) than the first (upstream) side 324 of the heat exchanger 320 is to the outlet 122 (and the outer edge 336 of the circuit board 310).

In some examples, one of the portions 332, 334 of the heat exchanger 320 may be omitted. That is, in some examples, the heat exchanger is positioned on only one surface 312, 314 of the circuit board 310 (e.g., when the computing device 100 is designed so that the air flow 308 predominately (e.g., exclusively) travels across the corresponding surface 312, 314 of the circuit board 310). Further, in some examples, other components shown in FIG. 3 may be omitted and/or in different locations than shown in the illustrated example. For instance, in some examples, the heat producing component 316 (along with the vapor chamber 318) may be on the opposite side of the circuit board 310 (e.g., on the second surface 314 facing the D cover 116 instead of on the first surface 312 facing the C cover 114. In some examples, multiple heat producing components 316 may be on one or both surfaces 312, 314 of the circuit board 310. Likewise, in some examples, multiple vapor chambers 318 may be positioned on one or both sides of the circuit board 310. In some examples, the vapor chamber 318 is omitted.

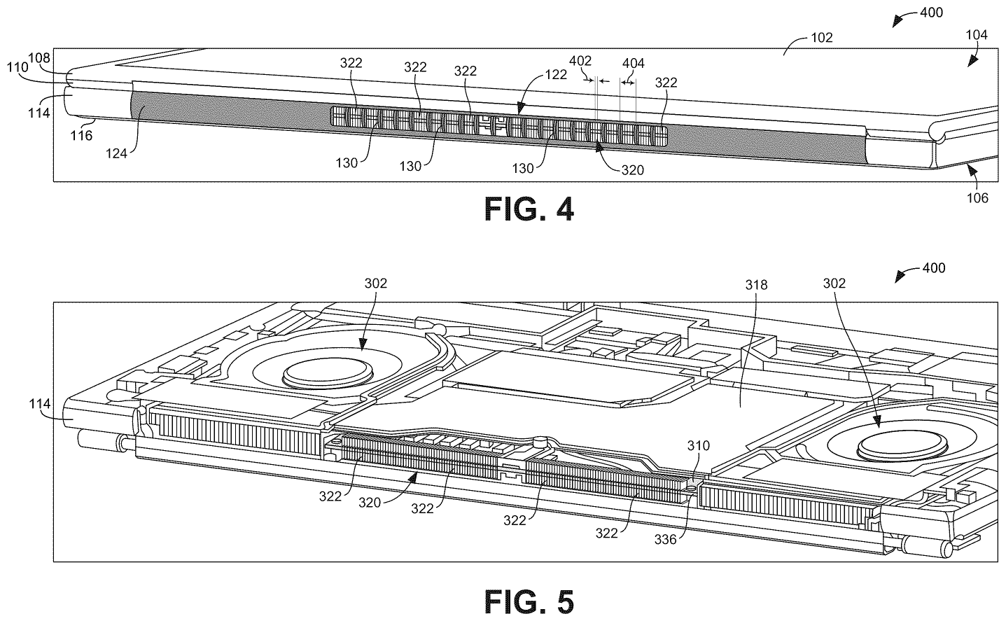

FIG. 4 is an isometric view of another example computing device 400 constructed in accordance with teachings disclosed herein. The computing device 400 of FIG. 4 is an example implementation of the example computing device 100 of FIGS. 1-3. Accordingly, the reference numerals used in FIGS. 1-3 are used for the same or similar features shown in FIG. 4 and the description of those features provided above applies equally to the corresponding features shown in FIG. 4. In the illustrated example of FIG. 4, the rear edge 124 of the base 106 is shown with the lid 104 in a closed position against the base 106. As shown in FIG. 4, the rear edge 124 of the base 106 includes the opening or outlet 122 that is supported by a plurality of ribs 130. Through the ribs 130, an array of the fins 322 of the heat exchanger 320 are visible in FIG. 4. The heat exchanger 320 and the array of fins 322 are shown more clearly in the illustrated example of FIG. 5.

FIG. 5 is an isometric view of the example computing device 400 of FIG. 4 except that the computing device has been inverted or flipped over and the external chassis or housing 102 (e.g., the A cover 108, the B cover 110, the C cover 114, and the D cover 116) has been removed to expose the internal components. Specifically, FIG. 5 shows the fan 302 (e.g., two fans in this example), the vapor chamber 318, the circuit board 310 (underneath the vapor chamber 318), and the heat exchanger 320 extending along the outer edge 336 of the circuit board 310. As shown in the illustrated example of FIGS. 4 and 5, the heat exchanger 320 (defined by an array of fins 322) extends along a substantial portion (all, substantially all, a majority, etc.) of the length of the outlet 122. As shown in FIG. 4, the pitch or spacing 402 of the fins 322 is smaller than the pitch or spacing 404 of the ribs 130. In some examples, the spacing 402 of the fins 322 is less than or equal to 1.0 mm to serve the function of a grill or mesh between the ribs 130 that satisfies safety requirements to block or prevent small objects from entering through the outlet 122. In some examples, the spacing 402 of the fins is significantly less than 1.0 mm (e.g., less than or equal to 0.8 mm, less than or equal to 0.5 mm, less than or equal to 0.2 mm, etc.) to enable more fins to fit along the length of the opening and increase the total surface area across which the air flow 308 passes to increase heat transfer. Inasmuch as the ribs 130 do not need to be relied on to block small objects, there is less need to position the ribs 130 close together. As a result, fewer ribs 130 are needed across the length of the outlet 122 and, therefore, the proportion of the opening of the outlet 122 blocked by the ribs 130 can be reduced to increase the open-air ratio of the outlet 122. In some examples, the pitch 404 of the ribs 130 is at least 3.0 mm or more (e.g., at least 5 mm, at least 7 mm, at least 10 mm, etc.). In some examples, the open-air ratio of the outlet 122 is greater than 71% (e.g., at least 72%, at least 73%, at least 74%, at least 75%, at least 76%, at least 77%, etc.). This open-air ratio is higher than other known cooling systems and testing has shown that such an open-air ratio provides an improvement in the outgoing flow rate of the air and a corresponding improvement in the cooling efficiency of the system.

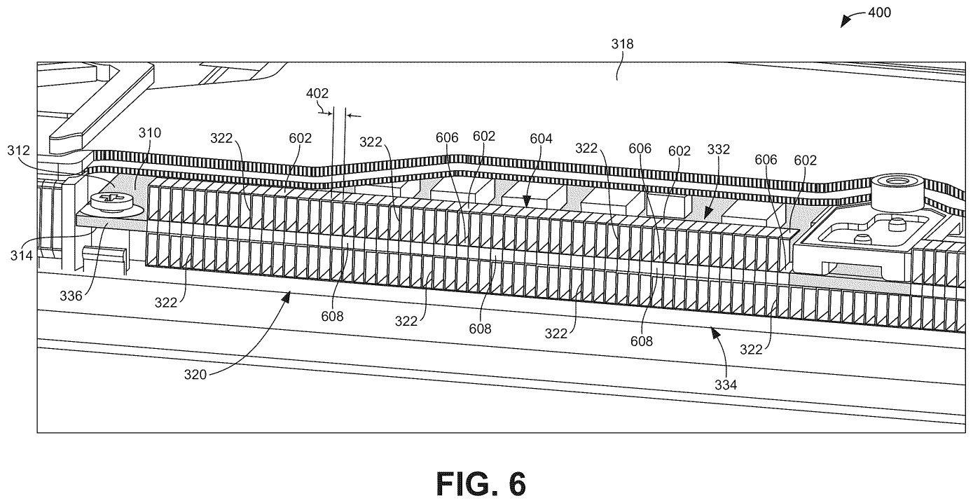

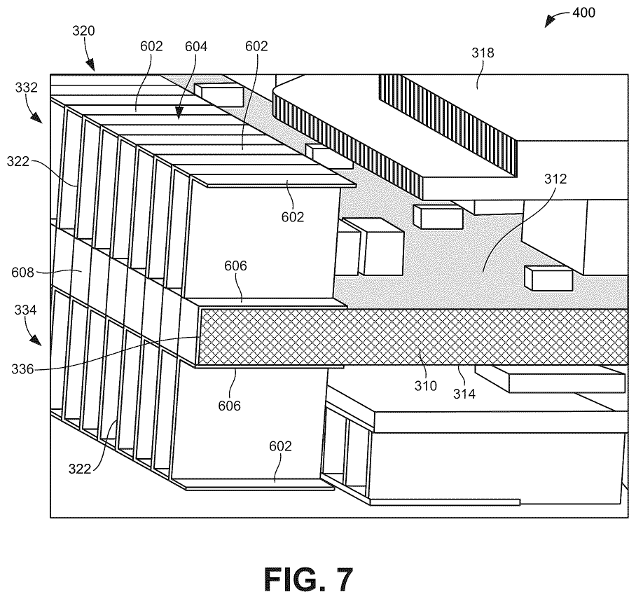

FIG. 6 is an enlarged view of a portion of the heat exchanger 320 of the example computing device 400 shown in FIG. 5. FIG. 7 is an enlarged cross-sectional view of a portion of the heat exchanger 320 of the example computing device 400 shown in FIG. 6. As shown in the illustrated examples, the heat exchanger 320 includes an array of individual fins 322 distributed along the outer edge 336 of the circuit board 310. Further, in this example, the fins 322 protrude away from both surfaces 312, 314 of the circuit board 310 and are orientated in a direction that extends transverse to the outer edge 336 of the board 310 (e.g., in a direction aligned with the air flow 308 shown in FIG. 3). In some examples, the individual fins 322 include corresponding outer flanges 602 at distal ends of the fins 322 farthest away from the circuit board 310. In some examples, the outer flanges 602 extend a distance corresponding to the spacing 402 of the fins 322 to enclose air passageways between adjacent ones of the fins 322. In some examples, the outer flanges 602 collectively define an outer surface 604 of the heat exchanger 320. In some examples, a continuous plate extends across the distal ends of the fins 322 in addition to or instead of the outer flanges 602 to define the outer surface 604.

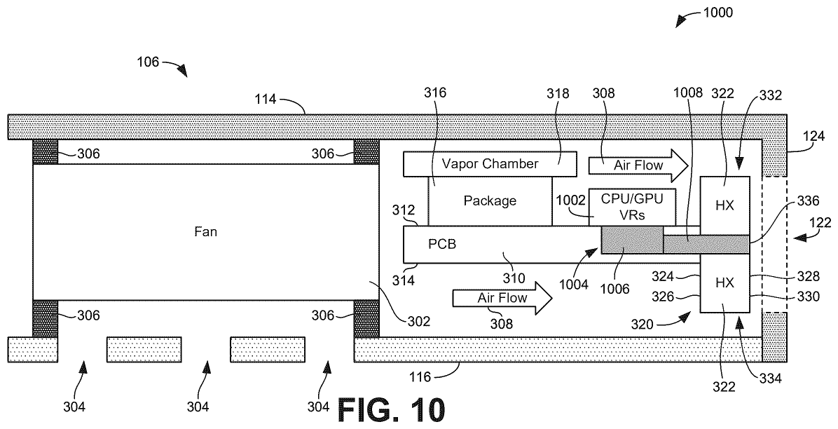

In some examples, the outer surface 604 of the heat exchanger 320 facilitates thermal coupling of the heat exchanger 320 with the vapor chamber 318 (partially cut-away in the illustrated example). In some examples, the outer surface 604 and the vapor chamber 318 are in direct contact. In some examples, a thermal interface material (TIM) is positioned between the outer surface 604 and the vapor chamber 318. In some examples the outer flanges 602 (and/or the corresponding continuous plate) are omitted. In some examples, the vapor chamber 318 is spaced apart from (e.g., not thermally coupled to) the heat exchanger 320. In some such examples, the heat producing component 316 may still be thermally coupled to the heat exchanger through other means. More particularly, in some examples, the heat producing component 316 is thermally coupled to the heat exchanger via a heat transfer path within the circuit board 310 as discussed further below in connection with FIGS. 10-12.

In some examples, the individual fins 322 include corresponding inner flanges 606 at proximal ends of the fins 322 closest to the circuit board 310. In some examples, the inner flanges 606 extend a distance corresponding to the spacing 402 of the fins 322 to enclose the air passageways between adjacent ones of the fins 322. In some examples, a continuous plate extends across the proximal ends of the fins 322 in addition to or instead of the inner flanges 606. In some examples, the inner flanges 606 (and/or a corresponding continuous plate) enables the heat exchanger 320 to be coupled to the circuit board 310. The heat exchanger 320 of the illustrated example can be coupled to the circuit board 310 in any suitable manner (e.g., using surface mount technology (SMT), soldering, thermal bonding, clamping, screwing, etc.). In some examples, the heat exchanger 320 is in direct contact with the circuit board 310. In some examples, a thermal interface material (TIM) is positioned between the heat exchanger 320 and the circuit board 310. In some examples the inner flanges 606 (and/or the corresponding continuous plate) are omitted.

As discussed above, in some examples, the heat exchanger 320 includes a first portion 332 on the first surface 312 of the circuit board 310 and a second portion 334 on the second (opposite) surface 314 of the circuit board 310. As shown in the illustrated example of FIG. 6, the first portion 332 includes a first array of the fins 322 and the second portion 334 includes a second array of the fins 322. In this example, the fins 322 are the same size and spaced apart by the same distance on both surfaces of the circuit board 310. However, in some examples, the fins 322 on one surface of the board 310 may be larger (e.g., if there is more clearance on one side than the other) and/or spaced apart at a different pitch than the fins 322 on the other surface of the board 310. In some examples, individual ones of the fins 322 include and/or are associated with a corresponding edge flange 608 that extends across (e.g., wraps around) the outer edge 336 of the circuit board 310. In some examples, the edge flanges 603 facilitate the thermal coupling of the fins 322 on either side of the circuit board 310. In some examples, a continuous plate extending the length of multiple (e.g., all) of the fins 322 in the array may be used to wrap around the outer edge 336 of the circuit board 310 in addition to or instead of the outer flanges 602. In some examples, the edge flanges 608 (and/or the corresponding continuous plate) are omitted.

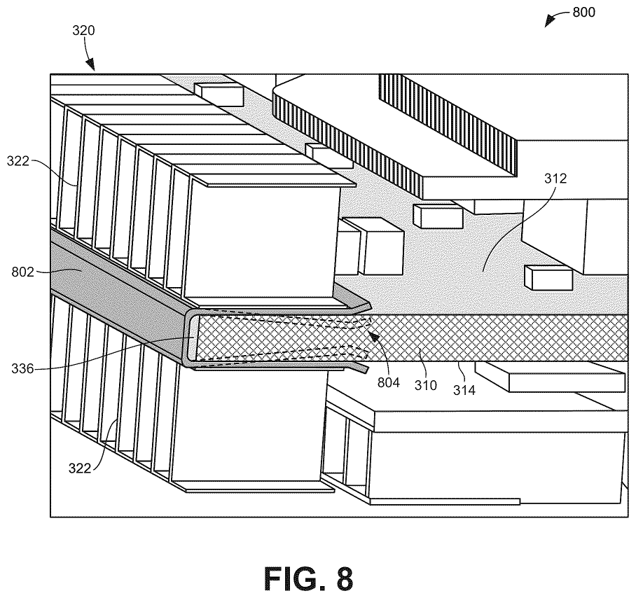

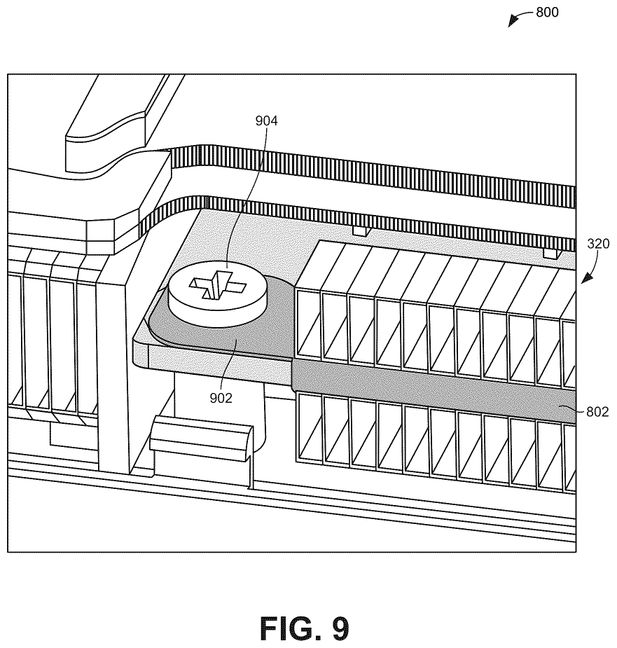

FIG. 8 is an enlarged cross-sectional view of another example computing device 800 constructed in accordance with teachings disclosed herein. The computing device 800 of FIG. 8 is another example implementation of the example computing device 100 of FIGS. 1-3 that is similar to the example computing device 400 of FIGS. 4-7 except as otherwise noted below. Thus, similar reference numerals used in FIGS. 1-7 are used for similar features shown in FIG. 8 and the description of those features provided above applies equally to the corresponding features shown in FIG. 8. In the illustrated example of FIG. 8, the array of fins 322 are coupled to a clip 802 that extends along the length of the heat exchanger 320 to enable the heat exchanger 320 to be removably coupled to the circuit board 310. In some examples, the clip 802 is flexible (e.g., is a spring clip) that can be expanded from a free position (indicated by the dashed lines 804 in FIG. 8) to fit over the outer edge 336 of the circuit board 310 into a mounted position (indicated by the solid lines in FIG. 8). In such examples, when attached to the circuit board 310, the flexible nature of the clip 802 produces a compressive force (e.g., a clamping force) on the opposing surfaces 312, 314 of the circuit board 310 to hold the heat exchanger 320 in place. In some examples, to prevent the clip 802 from slipping off the circuit board 310, the clip 802 includes one or more arms or tabs 902 including a hole through which the clip 802 can be secured to the circuit board 310 via a threaded fastener 904 as shown in FIG. 9. Specifically, in the illustrated example of FIG. 9, the tab 902 extends beyond the end of the heat exchanger 320. In other examples, the clip 802 includes one or more tabs positioned between the ends of the heat exchanger 320. In some such examples, the tab(s) extend in a direction away from the outer edge 336 of the circuit board 310.

FIG. 10 is another example computing device 1000 constructed in accordance with teachings disclosed herein. The computing device 1000 of FIG. 10 is similar to the example computing device 100 of FIGS. 1-3 except as otherwise noted below. Accordingly, the reference numerals used in FIGS. 1-3 are used for the same or similar features shown in FIG. 10 and the description of those features provided above applies equally to the corresponding features shown in FIG. 10. In the illustrated example of FIG. 10, the computing device 1000 includes the same heat producing component 316 as shown in FIG. 3 as well as a second heat producing component 1002. In this example, the second heat producing component 1002 corresponds to one or more voltage regulators (VRs) for a CPU and/or a GPU. However, in other examples, the second heat producing component 1002 can be any other suitable electronic device (e.g., video random access memory (VRAM) for a GPU, an integrated circuit, etc.). Although two heat producing components 316, 1002 are shown in FIG. 10, in other examples, any other suitable number heat producing components may be employed.

In the illustrated example of FIG. 10, the first heat producing component 316 is thermally coupled to the vapor chamber 318. However, unlike in FIG. 3, the vapor chamber 318 in the illustrated example of FIG. 10 is spaced apart from the heat exchanger 320. Thus, in this example, the first heat producing component 316 is not thermally coupled to the heat exchanger 320. Separating the vapor chamber 318 from the heat exchanger 320 enables the air flow 308 to pass between the vapor chamber 318 and the heat exchanger 320 to provide a different flow pattern that may facilitate thermal cooling depending on the design of the computing device 1000. In other examples, the vapor chamber 318 extends to and is thermally coupled with the heat exchanger 320. In some such examples, the vapor chamber 318 is also thermally coupled to the second heat producing component 1002. In some examples, the vapor chamber 318 is thermally coupled to the second heat producing component 1002 but physically separated from (e.g., not thermally coupled to) the heat exchanger 320.

Regardless of whether the vapor chamber 318 (and, thus, the first heating producing component 316) is thermally coupled to the heat exchanger 320, in this example, the second heat producing component 1002 is thermally coupled to the heat exchanger 320. More particularly, in this example, the second heat producing component 1002 is thermally coupled to the heat exchanger 320 via a heat transfer path 1004 defined within the circuit board 310. That is, in this example, the heat transfer path 1004 is between the opposing first and second surfaces 312, 314 of the circuit board 310. As shown in FIG. 10, the heat transfer path 1004 is thermally coupled to the second heat producing component 1002 and extends to the outer edge 336 of the circuit board 310. The first and second portions 332, 334 of the heat exchanger 320 are thermally coupled to either side of the heat transfer path 1004.

In some examples, the heat transfer path 1004 includes a heat extracting element 1006 positioned inside the circuit board 310 adjacent to (e.g., below) the second heating producing component 1002. In some examples, the heat extracting element 1006 is implemented by at least one of a metal (e.g., copper) slug or a heat pipe. In some examples, multiple copper slugs and/or multiple heat pipes may be employed. The heat extracting element 1006 is thermally coupled to the heat exchanger 320 via a metal (e.g., copper) layer 1008 in the printed circuit board. In some examples, the metal layer 1008 corresponds to one or more metal layers used for electrical routing throughout the circuit board 310. That is, in some examples, the metal layer 1008 includes multiple layers of metal separated by one or more dielectric layers. In other examples, the metal layer 1008 is a solid body of metal thicker than the metal layers used for electrical routing in the circuit board 310. In some examples, the metal layer 1008 is an integral extension of the heat extracting element 1006. In some examples, as shown in FIG. 10, the metal layer extends out to and defines the outer edge 336 of the circuit board 310, while other layers in the circuit board 310 (e.g., on either side of the metal layer 1008) extend up to but not beyond the first (upstream) side 324 of the heat exchanger 320. Thus, as shown in the illustrated example, the first and second portions 332, 334 of the heat exchanger 320 are closer to one another than the outer surfaces 312, 314 of the circuit board 310. However, as shown in the illustrated example, at least a part of the circuit board 310 (corresponding to the metal layer 1008) is disposed between the first and second portions 332, 334 of the heat exchanger 320.

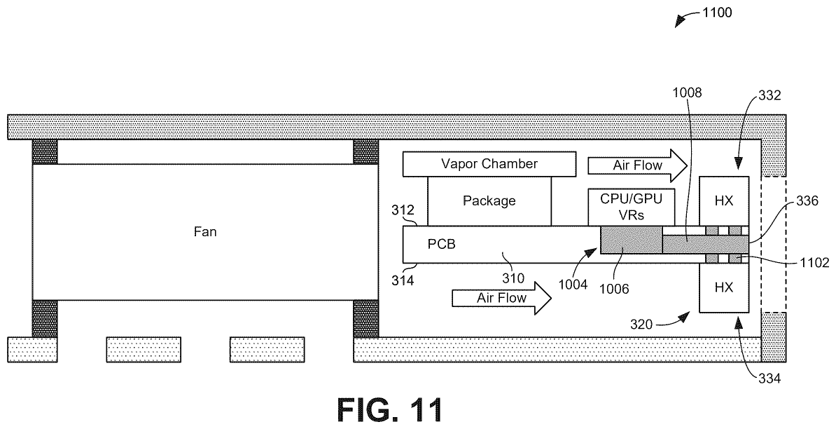

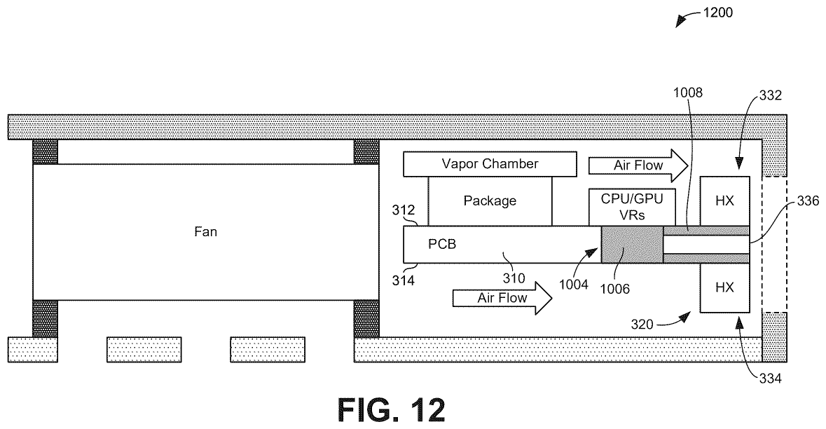

In other examples, the two portions 332, 334 of the heat exchanger 320 are positioned on the outer surfaces 312, 314 of the circuit board 310 as shown in the example computing device 1100 of FIG. 11. In such examples, the metal layer 1008 is thermally coupled to the heat exchanger 320 via one or more metal slugs or vias 1102 extending through outer layers of the circuit board 310. In this manner, the space within the outer layers of the circuit board 310 between the portions 332, 334 of the heat exchanger 320 remain available for electrical routing as discussed above in connection with the electrical routing 338 shown in FIG. 3. In other examples, the metal layer 1008 thermally coupling the heat extracting element 1006 to the heat exchanger 320 is implemented by a layer of metal extending along one or both outer surfaces 312, 314 of the circuit board 310 as shown in the example computing device 1200 of FIG. 12. In such examples, the layers of the circuit board 310 toward the middle (e.g., between the layers of metal associated with the metal layer 1008 in FIG. 12) that are overlapped by the heat exchanger 320 (e.g., between the two portions 332, 334 of the heat exchanger 32) can be used for electrical routing as discussed above in connection with the electrical routing 338 shown in FIG. 3.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs), one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that improve the efficiency of hyperbaric cooling systems of computing devices by increasing the open-air ratio of an air flow outlet through the use of heat exchanger fins along the outlet rather than thicker meshes, grills, and/or ribs. In some examples, the fins are positioned on one or both opposing surfaces of a circuit board so that the circuit board can extend out towards an outer side of the fins facing the outlet. As a result, no board space is lost by the placement of the fins, thereby providing additional space for electrical routing within the circuit board (e.g., at regions overlapped by the fins). Further, in some examples, the fins are thermally coupled to heat producing components within the computing device to facilitate the dissipation of heat. This thermal coupling can be achieved through a heat transfer path defined within a circuit board and/or via a vapor chamber external to the circuit board.

Disclosed systems, apparatus, articles of manufacture, and methods are accordingly directed to one or more improvement(s) in the operation of a machine such as a computer or other electronic and/or mechanical device.

Further examples and combinations thereof include the following:

Example 1 includes an apparatus comprising a housing including an air flow outlet, a circuit board, and a heat exchanger extending along an edge of the circuit board, the heat exchanger including a first side and a second side opposite the first side, the first side facing away from the outlet, the second side facing toward the outlet, wherein the edge of the circuit board is closer to the second side of the heat exchanger than the edge is to the first side of the heat exchanger.

Example 2 includes the apparatus of example 1, wherein the

heat exchanger includes fins extending transverse to the first and second sides of the heat exchanger.

Example 3 includes the apparatus of example 2, wherein adjacent ones of the fins are spaced apart at a pitch of less than or equal to about 1 millimeter.

Example 4 includes the apparatus of any one of examples 1-3, wherein the second side of the heat exchanger is adjacent to the outlet to block objects from entering the housing through the outlet.

Example 5 includes the apparatus of any one of examples 1-4, wherein the outlet and the heat exchanger define an open-air ratio greater than about 71%.

Example 6 includes the apparatus of any one of examples 1-5, further including an electronic component on the circuit board, the circuit board defining a heat transfer path between the electronic component and the heat exchanger.

Example 7 includes the apparatus of example 6, wherein the heat transfer path includes at least one of a copper slug or a heat pipe.

Example 8 includes the apparatus of any one of examples 6 or 7, wherein the heat transfer path includes a metal layer extending between outer surfaces of the circuit board.

Example 9 includes the apparatus of example 8, wherein the circuit board includes an electrical circuit path within a region of the circuit board overlapped by a portion of the heat exchanger, the electrical circuit path between the metal layer and the portion of the heat exchanger.

Example 10 includes the apparatus of example 8, wherein the circuit board includes an electrical circuit path within a region of the circuit board overlapped by a portion of the heat exchanger, the metal layer between the electrical circuit path and the portion of the heat exchanger.

Example 11 includes the apparatus of any one of examples 1-10, wherein the heat exchanger includes a first portion and a second portion, the first portion on a first surface of the circuit board and the second portion on a second surface of the circuit board, the first surface opposite the second surface, the first portion opposite the second portion.

Example 12 includes the apparatus of example 11, wherein the heat exchanger wraps around the edge of the circuit board.

Example 13 includes the apparatus of any one of examples 1-12, wherein the heat exchanger includes a clip to removably couple the heat exchanger to the circuit board.

Example 14 includes the apparatus of any one of examples 1-13, wherein the heat exchanger includes a tab, a threaded fastener to extend through the tab to couple the heat exchanger to the circuit board.

Example 15 includes the apparatus of any one of examples 1-14, further including an electronic component on the circuit board, and a vapor chamber thermally coupled to the electronic component and thermally coupled to the heat exchanger.

Example 16 includes an apparatus comprising a circuit board, a heat producing component on the circuit board, and an array of fins overlapping a region of the circuit board, the region defining an outer edge of the circuit board, individual fins of the array of fins orientated to extend between the heat producing component and the outer edge of the circuit board to enable a flow of air to sequentially pass across the heat producing component and between adjacent fins.

Example 17 includes the apparatus of example 16, wherein the circuit board includes electrical routing within the region of the circuit board overlapped by the array of fins.

Example 18 includes the apparatus of example 16, wherein the heat producing component is thermally coupled to the array of fins through the circuit board.

Example 19 includes a laptop comprising, a circuit board supporting electronic circuitry, a housing including an outlet, a fan to blow air across the electronic circuitry and out through the outlet, and a heat exchanger including an array of fins distributed along an outer edge of the circuit board, the heat exchanger along a length of the outlet, the fins including upstream edges facing away from the outlet and downstream edges facing towards the outlet, the outer edge of the circuit board closer to the outlet than the upstream edges of the fins are to the outlet.

Example 20 includes the laptop of example 19, wherein the circuit board includes a metal layer extending between the electronic circuitry and the heat exchanger, the metal layer thermally coupled to the heat exchanger.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a housing including an outlet for air flow;
a circuit board in the housing; and
a heat exchanger extending along an edge of the circuit board, the heat exchanger including a first side and a second side opposite the first side, the first side facing away from the outlet, the second side facing toward the outlet, wherein the edge of the circuit board is closer to the second side of the heat exchanger than the edge is to the first side of the heat exchanger.

2. The apparatus of claim 1, wherein the heat exchanger includes fins extending transverse to the first and second sides of the heat exchanger.

3. The apparatus of claim 2, wherein adjacent ones of the fins are spaced apart at a pitch of less than or equal to about 1 millimeter.

4. The apparatus of claim 1, wherein the second side of the heat exchanger is adjacent to the outlet to block objects from entering the housing through the outlet.

5. The apparatus of claim 1, wherein the outlet and the heat exchanger define an open-air ratio greater than about 71%.

6. The apparatus of claim 1, further including an electronic component on the circuit board, the circuit board defining a heat transfer path between the electronic component and the heat exchanger.

7. The apparatus of claim 6, wherein the heat transfer path includes at least one of a copper slug or a heat pipe.

8. The apparatus of claim 6, wherein the heat transfer path includes a metal layer extending between outer surfaces of the circuit board.

9. The apparatus of claim 8, wherein the circuit board includes an electrical circuit path within a region of the circuit board overlapped by a portion of the heat exchanger, the electrical circuit path between the metal layer and the portion of the heat exchanger.

10. The apparatus of claim 8, wherein the circuit board includes an electrical circuit path within a region of the circuit board overlapped by a portion of the heat exchanger, the metal layer between the electrical circuit path and the portion of the heat exchanger.

11. The apparatus of claim 1, wherein the heat exchanger includes a first portion and a second portion, the first portion on a first surface of the circuit board and the second portion on a second surface of the circuit board, the first surface opposite the second surface, the first portion opposite the second portion.

12. The apparatus of claim 11, wherein the heat exchanger wraps around the edge of the circuit board.

13. The apparatus of claim 1, wherein the heat exchanger includes a clip to removably couple the heat exchanger to the circuit board.

14. The apparatus of claim 1, wherein the heat exchanger includes a tab, a threaded fastener to extend through the tab to couple the heat exchanger to the circuit board.

15. The apparatus of claim 1, further including;
an electronic component on the circuit board; and
a vapor chamber thermally coupled to the electronic component and thermally coupled to the heat exchanger.

16. An apparatus comprising:
a circuit board;
a heat producing component on the circuit board; and
an array of fins overlapping a region of the circuit board, the region defining an outer edge of the circuit board, individual fins of the array of fins orientated to extend between the heat producing component and the outer edge of the circuit board to enable a flow of air to sequentially pass across the heat producing component and between adjacent fins.

17. The apparatus of claim 16, wherein the circuit board includes electrical routing within the region of the circuit board overlapped by the array of fins.

18. The apparatus of claim 16, wherein the heat producing component is thermally coupled to the array of fins through the circuit board.

19. A laptop comprising,
a circuit board supporting electronic circuitry;
a housing including an outlet;
a fan to blow air across the electronic circuitry and out through the outlet; and
a heat exchanger including fins distributed along an outer edge of the circuit board, the heat exchanger along a length of the outlet, the fins including upstream edges facing away from the outlet and downstream edges facing towards the outlet, the outer edge of the circuit board closer to the outlet than the upstream edges of the fins are to the outlet.

20. The laptop of claim 19, wherein the circuit board includes a metal layer extending between the electronic circuitry and the heat exchanger, the metal layer thermally coupled to the heat exchanger.
